(19) United States
(12) Patent Application Publication
(10) Pub. No.: US 2026/0060029 A1
(43) Pub. Date: Feb. 26, 2026

(54) SUBSTRATE PROCESSING APPARATUS

(71) Applicant: SCREEN Holdings Co., Ltd., Kyoto (JP)

(72) Inventor: Shota IWAHATA, Kyoto-shi (JP)

(21) Appl. No.: 19/299,254

(22) Filed: Aug. 13, 2025

(30) Foreign Application Priority Data
Aug. 23, 2024 (JP) 2024-141780

(51) Int. Cl. H01L 21/67; B01D 15/36; B01D 17/00

(52) U.S. Cl. CPC H10P 72/0424; B01D 15/361; B01D 17/085

(57) ABSTRACT

A substrate processing apparatus includes a chamber, a collection pipe, and a collection unit. In the chamber, a mixed solution of a chemical solution and an organic solvent acts on a main surface of a substrate. The collection pipe includes an upstream end portion connected to the chamber. The mixed solution from the chamber flows in the collection pipe. The collection unit includes a separation membrane separating the chemical solution from the mixed solution supplied through the collection pipe to increase a concentration of the organic solvent in the mixed solution.

### BACKGROUND

### TECHNICAL FIELD

The present disclosure relates to a substrate processing apparatus.

### DESCRIPTION OF THE BACKGROUND ART

Conventionally disclosed is a sheet-type substrate processing apparatus processing a substrate (for example, Japanese Patent Application Laid-Open No. 2021-114569). In Japanese Patent Application Laid-Open No. 2021-114569, the substrate processing apparatus supplies an etching solution including an oxidizer, a catalyst, and a moisture regulator to a substrate to etch a molybdenum film on the substrate.

### SUMMARY

A substrate processing apparatus includes: a chamber in which a mixed solution of a chemical solution and an organic solvent acts on a main surface of a substrate; a collection pipe, with an upstream end portion connected to the chamber, into which the mixed solution from the chamber flows; and a collection unit including a separation membrane separating the chemical solution from the mixed solution supplied through the collection pipe to increase a concentration of the organic solvent in the mixed solution.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example of a configuration of a substrate processing apparatus.

FIG. 2 is a block diagram schematically illustrating an example of a configuration of an inner configuration of a controller.

FIG. 3 is a diagram schematically illustrating an example of a configuration of a processing unit.

FIG. 4 is a diagram schematically illustrating an example of a configuration of a collection unit.

FIG. 5 is a diagram schematically illustrating a first another example of a configuration of the substrate processing apparatus.

FIG. 6 is a diagram schematically illustrating a second another example of a configuration of the substrate processing apparatus.

### DESCRIPTION OF THE PREFERRED EMBODIMENTS

An etching solution after being used for etching a substrate is discarded, for example. When a moisture regulator is an organic solvent, large energy is necessary to discard the etching solution high in the organic solvent. Considered accordingly is separation of the organic solvent from the etching solution by distillation, for example, to reduce a contained amount of the organic solvent in the etching solution. However, energy necessary for the distillation is also large, and running cost is high.

Accordingly, an object of the present disclosure is to provide a substrate processing apparatus capable of separating a chemical solution from a mixed solution of the chemical solution and an organic solvent by low energy.

Embodiments are described hereinafter in detail with reference to the diagrams. It should be noted that dimensions of components and the number of components are illustrated in exaggeration or in simplified form, as appropriate, in the diagrams for the sake of easier understanding. The same reference numerals are assigned to parts having a similar configuration and function, and the repetitive description is omitted in the description hereinafter.

In the description hereinafter, the same reference numerals will be assigned to the similar constituent elements in the diagrams, and the constituent elements having the same reference numeral have the same name and function. Accordingly, the detailed description on them may be omitted to avoid a repetition in some cases.

In the following description, even when ordinal numbers such as “first” or “second” are stated, these terms are used to facilitate understanding of contents of embodiments for convenience, and therefore, the usage of the ordinal numbers does not limit the indication of the ordinal numbers to ordering.

Unless otherwise noted, the expressions indicating relative or absolute positional relationships (e.g., “in one direction”, “along one direction”, “parallel”, “orthogonal”, “central”, “concentric”, and “coaxial”) include not only those exactly indicating the positional relationships but also those where an angle or a distance is relatively changed within tolerance or to the extent that similar functions can be obtained. Unless otherwise noted, the expressions indicating equality (e.g., “same”, “equal”, and “uniform”) include not only those indicating quantitatively exact equality but also those in the presence of a difference within tolerance or to the extent that similar functions can be obtained. Unless otherwise noted, the expressions indicating shapes (e.g., “rectangular” or “cylindrical”) include not only those indicating geometrically exact shapes but also those indicating, for example, roughness or a chamfer to the extent that similar effects can be obtained. An expression “comprising”, “with”, “provided with”, “including”, or “having” a certain constituent element is not an exclusive expression for excluding the presence of the other constituent elements. An expression “at least one of A, B, and C” involves only A, only B, only C, arbitrary two of A, B, and C, and all of A, B, and C.

### Whole configuration of substrate processing apparatus

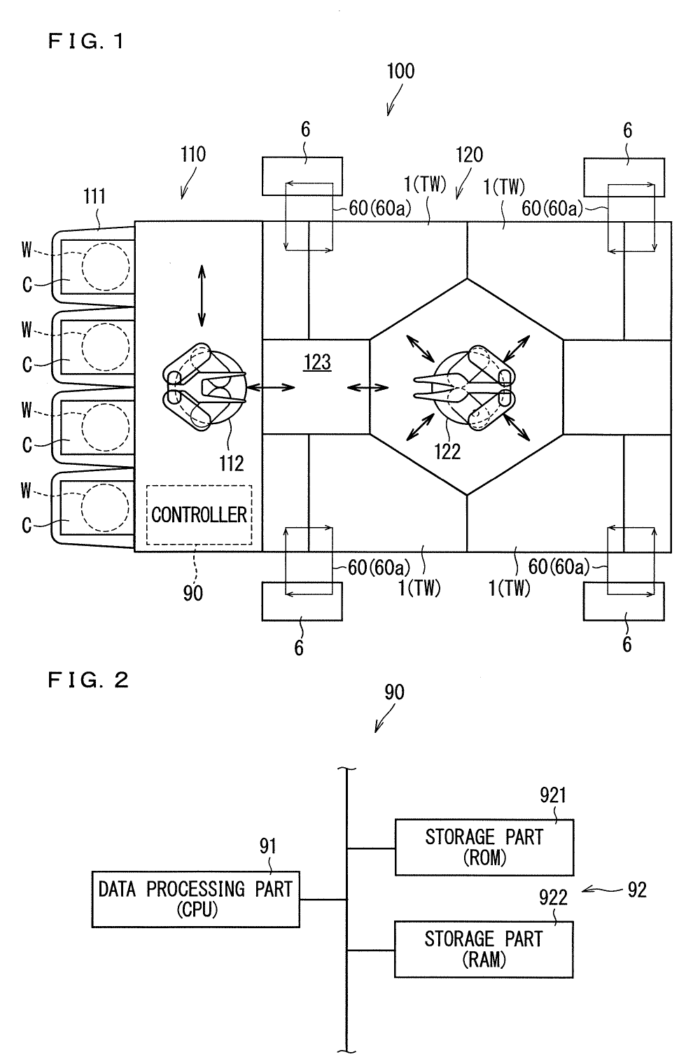

FIG. 1 is a plan view schematically illustrating an example of a configuration of a substrate processing apparatus 100. The substrate processing apparatus 100 is a sheet-like processing apparatus processing a substate W one by one. The substrate W is a semiconductor wafer such as a silicon semiconductor, for example. The substate W has a disk-like shape, for example. A diameter of the substate W is approximately 300 mm, for example, and a thickness of the substate W is approximately equal to or larger than 0.5 mm and approximately equal to or smaller than 3 mm, for example. The substrate W may be a substrate other than the semiconductor wafer.

In the example in FIG. 1, the substrate processing apparatus 100 includes an indexer block 110, a processing block 120, a collection unit (collection apparatus), and a controller 90. The processing block 120 is a part mainly processing the substate W, and the indexer block 110 is a part mainly transporting the substate W between an outer part of the substrate processing apparatus 100 and the processing block 120. The collection unit 6 is a unit receiving a processing solution after processing the substrate W from the processing block 120.

The indexer block 110 includes a load port 111 and a first transportation part 112. A substrate housing container (referred to as a carrier hereinafter) C transported from an outer part is disposed on the load port 111. The plurality of substrates W are housed in the carrier C while being arranged at intervals in a vertical direction, for example. In the example in FIG. 1, the plurality of load ports 111 are arranged.

The first transportation part 112 is a transportation robot and can also be referred to as an indexer robot. The first transportation part 112 transports the unprocessed substrate W from the carrier C to the processing block 120. The processing block 120 can process the substate W. The first transportation part 112 transports the substrate W which has been processed from the processing block 120 to the carrier C of the load port 111.

In the example in FIG. 1, the processing block 120 includes a plurality of processing units 1 and a second transport part 122. The second transport part 122 is a transport robot, and transports the substate W between the first transportation part 112 and the plurality of processing units 1. In the example 1, the processing block 120 also includes a mounting part 123. The mounting part 123 is a shelf on which the plurality of substrates W can be disposed to be arranged in a vertical direction, for example. The first transportation part 112 transports the unprocessed substrate W from the mounting part 123 to the processing unit 1. The processing unit 1 supplies the processing solution to the substrate W to process the substate W. A configuration of the processing unit 1 is described hereinafter. The second transport part 122 transports the substate W which has been processed from the processing unit 1 to the mounting part 123. The first transportation part 112 transports the substrate W which has been processed from the mounting part 123 to the carrier C of the load port 111.

In the example in FIG. 1, the plurality of (for example, four) processing units 1 are provided to surround the second transport part 122 in a plan view. The second transportation part 122 can also be referred to as a center robot. The plurality of processing units 1 may be stacked in a vertical direction in each position in a plan view. That is to say, a plurality of (for example, four) towers TW made up of the plurality of processing units 1 stacked in the vertical direction may be provided to surround the second transport part 122.

The collection unit 6 is connected to the processing unit 1 via a pipe 60. The processing solution used for processing the substrate W in the processing unit 1 is supplied to the collection unit 6 through the pipe 60. An example of a specific configuration of the collection unit 6 is described in details hereinafter.

The controller 90 collectively controls the substrate processing apparatus 100. Specifically, the controller 90 controls the first transportation part 112, the second transport part 122, the processing unit 1, and the collection unit 6. FIG. 2 is a block diagram schematically illustrating an example of an inner configuration of the controller 90. The controller 90 is an electrical circuit, and includes a data processing part 91 and a storage part 92, for example. In the specific example in FIG. 2, the data processing part 91 and the storage part 92 are mutually connected to each other via a bus 93. The data processing part 91 may be an arithmetic processing unit such as a central processor unit (CPU), for example. The storage part 92 may include a non-transitory storage part (for example, a read only memory (ROM)) 921 and a transitory storage part (for example, a random access memory (RAM)) 922. The controller 90 may also be connected to a non-transitory storage part (a memory or a hard disk) not shown in the diagrams. The non-transitory storage part 921 may store a program regulating processing executed by the controller 90, for example. When the data processing part 91 executes this program, the controller 90 can execute processing regulated by the program. Needless to say, hardware such as a dedicated logic circuit may execute a part of or whole processing executed by the controller 90.

### Outline of processing unit

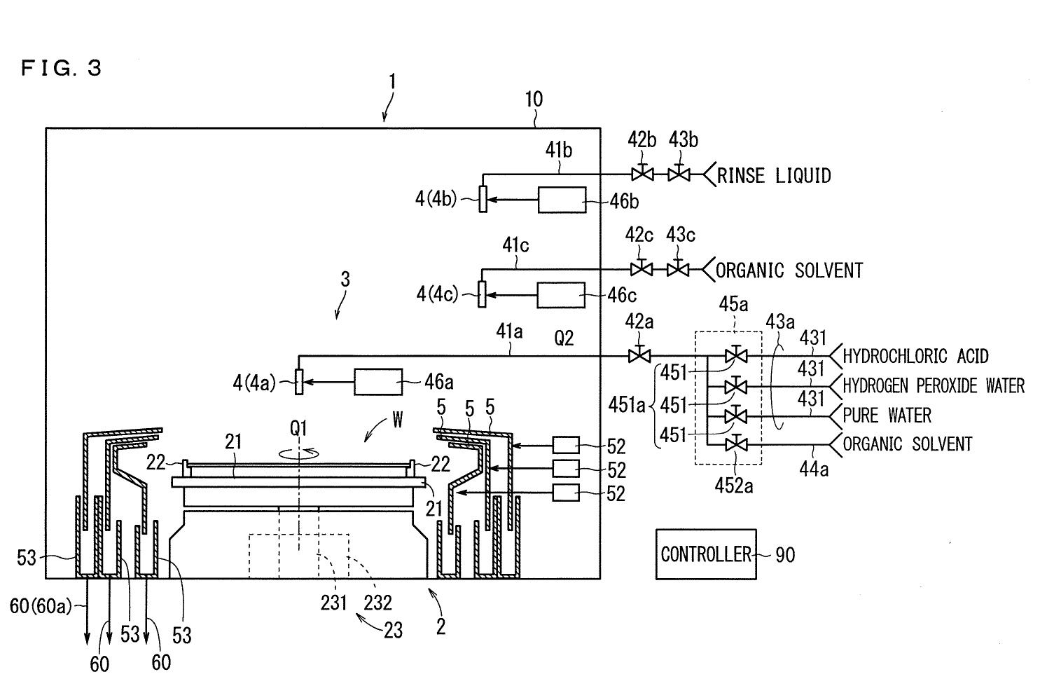

FIG. 3 is a diagram schematically illustrating an example of a configuration of the processing unit 1. All of the processing units 1 belonging to the substrate processing apparatus 100 need not have a configuration exemplified in FIG. 3. It is sufficient that at least one processing unit 1 in the substrate processing apparatus 100 has the configuration exemplified in FIG. 3.

The processing unit 1 supplies the processing solution to the main surface (main surface, for example) of the substrate W to process the substate W as described in details hereinafter. The processing solution includes an etching solution, for example. In this case, the processing unit 1 etches an etching target on the main surface of the substrate W. The etching target includes metal, for example. The etching target may be a metal compound of a metal nitride film and a metal oxide film, for example. The metal compound is TiN, TaN, TaAlN, or TiC, for example. A structure midway through a manufacture of a nano-sheet field effect transistor (FET) may be formed in the main surface of the substrate W. The nano-sheet FET is also referred to as a ribbon FET. In such a structure, a plurality of fin structures described next are arranged at intervals in a direction perpendicular to the main surface of the substrate W, for example. The fin structures include a sheet-like semiconductor layer and an insulating film surrounding the semiconductor layer. A sacrifice film is provided around the fin structures. The sacrifice film is the etching target herein.

The processing unit 1 includes a substrate holding part 2 and a discharge part 3. In the example in FIG. 3, the processing unit 1 also includes a chamber 10. The chamber 10 has a box-like shape, and an inner space thereof corresponds to a processing space for processing the substate W. An openable and closable transfer port (not shown) is provided to the chamber 10. The second transport part 122 transports the unprocessed substrate W into the chamber 10 through the transfer port, and transports the substrate W which has been processed from the chamber 10 through the transfer port.

The substrate holding part 2 is provided in the chamber 10, and rotates the substrate W around a rotation axis line Q1 while holding the substrate W in a horizonal posture. The horizontal posture herein indicates a posture in which a thickness direction of the substrate W extends along the vertical direction. The rotation axis line Q1 is an axis extending along the vertical direction through a center of the substrate W. Such a substrate holding part 2 can also be referred to as a spin chuck. The main surface of the substrate W in which a pattern (for example, a fin structure) is formed corresponds to an upper surface of the substrate W herein.

The substrate holding part 2 may hold the substate W by a chuck system such as mechanical chuck, vacuum chuck, electrostatic chuck, and Bernoulli chuck. In the example in FIG. 3, the substrate holding part 2 has a mechanical chuck system, and includes a spin base 21, a chuck pin 22, and a rotation driver 23. The spin base 21 has a plate-like shape (for example, a disk-like shape), and is provided so that a thickness direction thereof follows the vertical direction. The plurality of chuck pins 22 are provided on the spin base 21 at regular intervals along a circumferential direction of the rotation axis line Q1. The plurality of chuck pins 22 are provided to be able to be displaced between a holding position and a release position described next. The holding position is a position where the chuck pin 22 has direct contact with a peripheral edge of the substate W. When the plurality of chuck pins 22 stop at respective holding positions, the plurality of chuck pins 22 hold the substate W (refer to FIG. 3). The release position is a position where each chuck pin 22 is away from the substate W. When the plurality of chuck pins 22 stop at respective release positions, holding of the substate W by the plurality of chuck pins 22 is released. The substrate holding part 2 also includes a pin driver (not shown) displacing the chuck pin 22. The pin driver includes a drive source such as a motor or an air cylinder, for example, and is controlled by the controller 90.

The rotation driver 23 includes a shaft 231 and a motor 232. An upper end of the shaft 231 is connected to a lower surface of the spin base 21, and the shaft 231 extends along the rotation axis line Q1 from the lower surface of the spin base 21. The motor 232 is controlled by the controller 90, and rotates the shaft 231 around the rotation axis line Q1. Accordingly, the spin base 21, the chuck pin 22, and the substate W are integrally rotated around the rotation axis line Q1.

The discharge part 3 discharges various processing solutions toward the main surface (upper surface herein) of the substrate W held by the substrate holding part 2. The processing solution reaching the main surface of the substrate W flows to an outer side in a radial direction in accordance with the rotation of the substrate W, and flies outside from the main surface of the substrate W. Accordingly, the processing solution acts on the main surface of the substate W.

A mixed solution of a chemical solution and an organic solvent is adopted as one of the processing solutions. The chemical solution is a liquid for etching the etching target. Specifically, the chemical solution may be dilute hydrofluoric acid, a mixture of hydrochloric acid, hydrogen peroxide water, and water (SC2), a mixture of ammonia water, hydrogen peroxide water, and water (SC1), or diluted hydrogen peroxide water. An etching solution other than that described above can also be adopted. A concentration (vol %) of dilute hydrofluoric acid may be approximately 1:5 to 1:2000 as a notation of hydrogen fluoride: pure water, for example. A concentration (vol %) of SC1 may be approximately 1:1:5 to 1:1:100 as a notation of sulfuric acid: hydrogen peroxide water: pure water, for example. A concentration (vol %) of SC2 may be approximately 1:1:5 to 1:1:100 as a notation of ammonia water: hydrogen peroxide water: pure water, for example.

The organic solvent may be isopropyl alcohol or methanol. When such an organic solvent is mixed into the chemical solution, electrical conductivity of the mixed solution can be increased. A concentration of the organic solvent in the mixed solution (referred to as a solvent concentration hereinafter) may be equal to or higher than 5 vol % and equal to or lower than 80 vol %, or may also be equal to or higher than 30 vol % and equal to or lower than 70 vol %. When such a mixed solution acts on the etching target of the substrate W, a supply amount of electrons increases. Thus, etching reaction is activated. Thus, an etching speed can be increased.

A surface tension of the organic solvent may be larger than that of the chemical solution. In this case, the mixed solution easily enters between patterns of the substrate W (between the fin structures, for example), and the etching target can be etched more rapidly.

A molecule diameter of each molecule of the organic solvent is larger than that (maximum value) of each molecule of the chemical solution. Thus, as described in details hereinafter, the collection unit 6 can separate the chemical solution from the mixed solution after processing the substrate W using a difference of the molecule diameter.

In the example in FIG. 3, the discharge part 3 includes a nozzle 4. The nozzle 4 is a straight nozzle discharging a liquid column-like processing solution, for example. The nozzle 4 is provided above the substrate W held by the substrate holding part 2 in the chamber 10. The nozzle 4 discharges the processing solution toward the main surface of the substrate W.

In the example in FIG. 3, the plurality of nozzles 4 are provided, and a nozzle 4a for the mixed solution is provided as one of the nozzles 4. A downstream end portion of a mixing pipe 41a is connected to the nozzle 4a, and an upstream end portion of the mixing pipe 41a is connected to a mixing part 45a. A downstream end portion of a chemical solution supply pipe 43a and a downstream end portion of a solvent supply pipe 44a are also connected to the mixing part 45a. In the example in FIG. 3, the chemical solution supply pipe 43a includes a plurality of individual supply pipes 431 corresponding to plural types of liquids constituting the chemical solution. SC2 is adopted to the chemical solution as an example herein. Thus, provided are the individual supply pipe 431 in which hydrochloric acid flows, the individual supply pipe 431 in which hydrogen peroxide water flows, and the individual supply pipe 431 in which pure water flows. The organic solvent flows in the solvent supply pipe 44a.

The mixing part 45a mixes the chemical solution flowing from the chemical solution supply pipe 43a and the organic solvent flowing from the solvent supply pipe 44a. The mixing part 45a may be a multiple valves. The mixing part 45a includes a chemical solution mixing valve 451a and a solvent mixing valve 452a, for example. In the example in FIG. 3, the chemical solution mixing valve 451a includes a plurality of individual mixing valves 451 corresponding to a plurality of liquids constituting the chemical solution. For example, the chemical solution mixing valve 451a includes the individual mixing valve 451 for hydrochloric acid, the individual mixing valve 451 for hydrogen peroxide water, and the individual mixing valve 451 for pure water. Each individual mixing valve 451 passes each liquid toward the mixing pipe 41a at a flow amount corresponding to an opening degree of itself. The solvent mixing valve 452a passes the organic solvent toward the mixing pipe 41a at a flow amount corresponding to an opening degree of itself. The controller 90 controls the chemical solution mixing valve 451a and the solvent mixing valve 452a. The mixing part 45a is not necessarily limited to the multiple valves, but may be made up of a connection part of connecting pipes and a flow amount adjustment valve connected to each pipe.

A supply valve 42a is inserted into the mixing pipe 41a to switch opening and closing of the mixing pipe 41a. The controller 90 controls the supply valve 42a.

In the example in FIG. 3, the nozzle 4a can be moved by a movement driver 46a. The movement driver 46a moves the nozzle 4a between a processing position and a standby position described next. The processing position is a position where the nozzle 4a discharges the mixed solution, and is a position facing a center part of the substrate W in the vertical direction (refer to FIG. 3). The standby position is a position where the nozzle 4a does not discharge the mixed solution, and is a position outside the substate W in a radial direction, for example. The movement driver 46a includes a drive source such as a motor and a power transmission part connecting the driver source and a nozzle, for example. The power transmission part includes an arm slewing mechanism or a ball spring mechanism, for example.

In the example in FIG. 3, a nozzle 4b for a rinse liquid is also illustrated as the nozzle 4. The nozzle 4b is connected to a downstream end portion of the supply pipe 41b, and an upstream end portion of the supply pipe 41b is connected to a rinse liquid supply source. The rinse liquid is pure water, for example. A supply valve 42b and a flow amount adjustment valve 43b are inserted into the supply pipe 41b. The supply valve 42b switches opening and closing of the supply pipe 41b, and the flow amount adjustment valve 43b adjusts a flow amount of the rinse liquid flowing in the supply pipe 41b. The controller 90 controls the supply valve 42b and the flow amount adjustment valve 43b. The nozzle 4b can be moved by a movement driver 46b. The movement driver 46b moves the nozzle 4b between a processing position and a standby position. The movement driver 46b has a configuration similar to the movement driver 46a, and is controlled by the controller 90, for example.

The processing unit 1 supplies the rinse liquid to the substrate W after supplying the mixed solution to the substate W. Accordingly, the mixed solution on the main surface of the substrate W can be washed away by the rinse liquid.

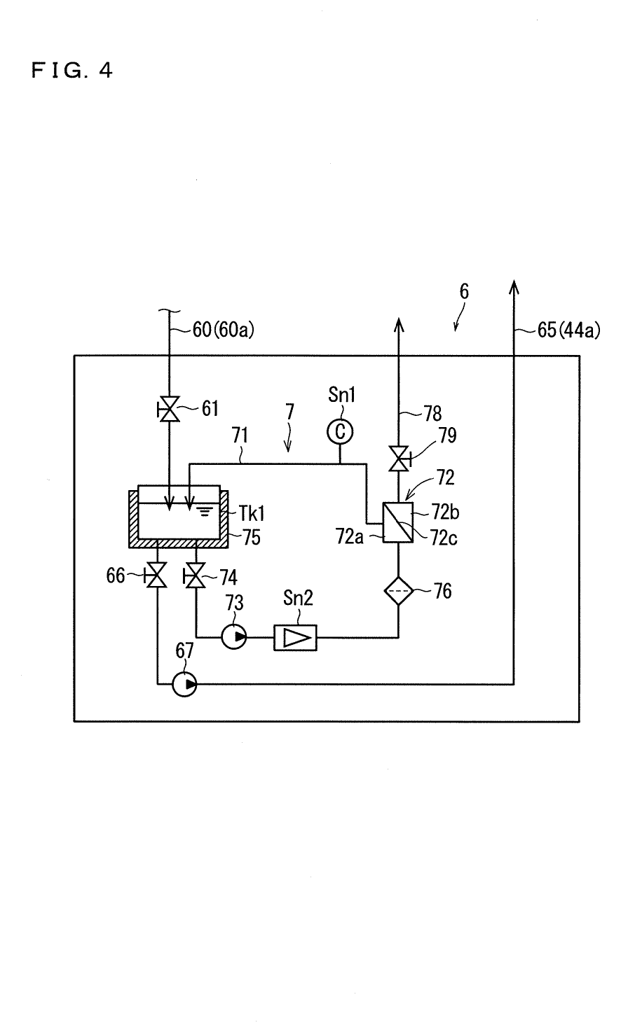

In the example in FIG. 4, a nozzle 4c for an organic solvent is also illustrated as the nozzle 4. The nozzle 4c is connected to a downstream end portion of the supply pipe 41c, and an upstream end portion of the supply pipe 41c is connected to an organic solvent supply source. A supply valve 42c and a flow amount adjustment valve 43c are inserted into the supply pipe 41c. The supply valve 42c switches opening and closing of the supply pipe 41c, and the flow amount adjustment valve 43c adjusts a flow amount of the organic solvent flowing in the supply pipe 41c. The controller 90 controls the supply valve 42c and the flow amount adjustment valve 43c. The nozzle 4c can be moved by a movement driver 46c. The movement driver 46c moves the nozzle 4c between a processing position and a standby position. The movement driver 46c has a configuration similar to the movement driver 46a, and is controlled by the controller 90.

The processing unit 1 supplies the organic solvent to the substrate W after supplying the rinse liquid to the substate W. Accordingly, the rinse liquid on the main surface of the substrate W can be washed away by the organic solvent. Volatility of the organic solvent is higher than that of the rinse liquid herein.

The processing unit 1 dries the substrate W after supplying the organic solvent. For example, when the substrate holding part 2 increases a rotational speed of the substate W, the substrate W is dried (so-called spin drying).

In the example in FIG. 3, a plurality of guards 5 are provided to the processing unit 1. Each guard 5 has a cylindrical shape with a rotation axis line Q1 as a center axis, and surrounds the substrate holding part 2. The plurality of guards 5 are concentrically provided. Each guard 5 can be lifted up and down by a lifting driver 52.The lifting driver 52 lifts up and down each guard 5 between an upper position and a lower position. The upper position is a position where an upper end of the guard 5 is located above the substrate W held by the substrate holding part 2. In this state, the guard 5 can receive the processing solution flying from the peripheral edge of the substrate W. For example, the lifting driver 52 includes a drive source such as a motor and a power transmission part such as a cam mechanism. The controller 90 controls the lifting driver 52.

Each guard 5 is used differently in accordance with a type of the processing solution. For example, the guard 5 on an outer side is used for the mixed solution. Specifically, the nozzle 4a discharges the mixed solution toward the main surface of the substrate W while the lifting driver 52 makes only the guard 5 on the outer side be located in the upper position. Accordingly, the mixed solution flying from the peripheral edge of the substrate W is received by the guard 5 on the outer side, and drops down along an inner peripheral surface of the guard 5.

In the example in FIG. 3, a cup 53 corresponding to each guard 5 is provided. The cup 53 includes an annular (toric, for example) concave part (groove) surrounding the rotation axis line Q1. Each cup 53 receives the processing solution flowing down the inner peripheral surface of the corresponding guard 5. An upstream end portion of the pipe 60 is connected to a bottom part, for example, of each cup 53. The processing solution received by each cup 53 is discharged outside the processing unit 1 through the pipe 60.

The mixed solution received by the guard 5 on the outer side is received by the corresponding cup 53, and flows in the corresponding pipe 60. The pipe 60 in which the mixed solution flows is also referred to as the collection pipe 60a hereinafter.

### Collection unit 6

FIG. 4 is a diagram schematically illustrating an example of a configuration of the processing unit 6. The collection unit 6 is connected to the processing unit 1 via a collection pipe 60a for the mixed solution. In the example in FIG. 4, a collection valve 61 is inserted into the collection pipe 60a. The collection valve 61 switches opening and closing of the collection pipe 60a. The controller 90 controls the collection valve 61.

The mixed solution after being used for processing the substrate W in the processing unit 1 (also referred to as the mixed solution after processing hereinafter) is supplied to the collection unit 6 through the collection pipe 60a. The collection unit 6 includes a membrane separator 72. The membrane separator 72 separates the chemical solution from the mixed solution after processing to increase a concentration of the solvent in the mixed solution. An example of a configuration of the collection unit 6 is specifically described hereinafter.

In the example in FIG. 4, the collection unit 6 includes a tank Tk1 and a circulation part 7. A downstream end portion of the collection pipe 60a is connected to the tank Tk1. Thus, the mixed solution after processing from the processing unit 1 flows in the tank Tk1 through the collection pipe 60a. The tank Tk1 stores the mixed solution.

A buffer tank (not shown) may be inserted into the collection pipe 60a. In this case, a solution sending part such as a pump and a supply valve may be inserted into the collection pipe 60a between the buffer tank and the tank Tk1. In this case, the mixed solution after processing from the processing unit 1 is once stored in the buffer tank, and is subsequently supplied from the buffer tank to the tank Tk1.

The circulation part 7 includes a circulation pipe 71, the membrane separator 72, a solution sending part 73, and a circulation valve 74. The circulation pipe 71 forms a circulation route in which the mixed solution stored in the tank Tk1 is circulated to flow from the tank Tk1 and return to the tank Tk1 again. An upstream end potion of the circulation pipe 71 is connected to a bottom part, for example, of the tank Tk1, and a downstream end portion of the circulation pipe 71 is connected to an upper part, for example, of the tank Tk1.

The membrane separator 72 is inserted into the circulation pipe 71. The membrane separator 72 includes a housing, and includes a first route 72a, a second route 72b, and a separation membrane 72c in the housing. The first route 72a is inserted into the circulation pipe 71 to constitute a part of the circulation route of the circulation part 7. Thus, the mixed solution passes through the first route 72a. The separation membrane 72c partitions the first route 72a and the second route 72b. The separation membrane 72c is a membrane passing the chemical solution and blocking almost the organic solvent in the mixed solution. A part of the chemical solution in the mixed solution flowing in the first route 72a passes through the separation membrane 72c to flow in the second route 72b.

The separation membrane 72c is a pore membrane, and separates the chemical solution from the mixed solution based on a difference of the molecular diameter between the chemical solution and the organic solvent. The molecule diameter of the chemical solution is smaller than that of the organic solvent. A size of a pore in the separation membrane 72c is set such that the separation membrane 72c substantially blocks each molecule of the organic solvent and passes the molecules of the chemical solution. Thus, each molecule of the chemical solution can pass through the pore of the separation membrane 72c, and each molecule of the organic solvent can hardly pass through the pore of the separation membrane 72c. The difference of the molecule diameter between the organic solvent and the chemical solution may be equal to or larger than 0.5 Å, or may also be equal or larger than 1 Å, for example. For example, a molecule diameter of isopropyl alcohol is approximately 6.2 Å, and a maximum molecule diameter of molecules of compounds constituting the chemical solution (for example, SC1, SC2, or ammonia water) is approximately equal to or smaller than 5.0 Å.

The separation membrane 72c may be a zeolite membrane, an organic separation membrane, or a carbon nanotube (CNT) separation membrane. The zeolite membrane has a crystal structure that (SiO₄)⁴⁻ and (AlO₄)⁵⁻ having a tetrahedral structure are mutually bonded to each other, for example. The organic separation membrane is an organic membrane of polyvinyl alcohol, chitosan, and polyimide, for example. The CNT separation membrane is a membrane obtained by adding carbon nanotube to a membrane of polyamide, for example. Alternatively, a two-dimensional material may be adopted as a material of the separation membrane 72c. The two-dimensional material is a material made up of a single layer of atoms, and may be molybdenum sulfide (MoS₂) or a composite atomic layer compound of pre-period transition metal (such as titanium and vanadium) and light elements (carbon or nitrogen). Alternatively, a metal organic frameworks (MOF) material or a carbon material (graphene or graphene oxide, for example) may be applied as a material of the separation membrane 72c. A zeolite membrane is applied as the separation membrane 72c herein.

An upstream end portion of a discharge pipe 78 is connected to the second route 72b. A liquid (mainly a chemical solution) passing through the separation membrane 72c in the mixed solution is discharged outside (for example, a discharge solution processing part in a plant facility) through the discharge pipe 78. A decompression pump reducing pressure in the second route 72b may be provided to the discharge pipe 78. As illustrated in FIG. 4, the discharge valve 79 may be inserted into the discharge pipe 78. The discharge valve 79 switches opening and closing of the discharge pipe 78. The controller 90 controls the discharge valve 79.

The solution sending part 73 is inserted into the circulation pipe 71. In the example in FIG. 4, the solution sending part 73 is located upstream of the membrane separator 72. The solution sending part 73 is a pump, for example, and sends the mixed solution from an upstream end portion of the circulation pipe 71 toward a downstream end portion thereof. The circulation valve 74 is inserted into the circulation pipe 71. In the example in FIG. 4, the circulation valve 74 is located upstream of the solution sending part 73. The circulation valve 74 switches opening and closing of the circulation pipe 71. The controller 90 controls the solution sending part 73 and the circulation valve 74.

In the example in FIG. 4, the collection unit 6 also includes a temperature adjustment part 75. The temperature adjustment part 75 is controlled by the controller 90, and adjusts a temperature of the mixed solution. For example, the temperature adjustment part 75 may be a heater heating the mixed solution. As a specific example, the temperature adjustment part 75 may be an electric-resistive heater or an emission heater. In the example in FIG. 4, the temperature adjustment part 75 is provided to the tank Tk1, and heats the mixed solution in the tank Tk1. In the example in FIG. 4, the temperature adjustment part 75 is provided to a bottom part and a side part of the tank Tk1. The temperature adjustment part 75 adjusts the temperature of the mixed solution to a temperature appropriate for separation by the membrane separator 72. As a specific example, the temperature adjustment part 75 adjusts the temperature of the mixed solution to 70 degrees Celsius or more. The temperature adjustment part 75 may be provided to the circulation pipe 71.

In the example in FIG. 4, a flowmeter Sn2 is provided to the circulation pipe 71. The flowmeter Sn2 outputs a signal corresponding to a flow amount in the circulation pipe 71 to the controller 90. The controller 90 controls the solution sending part 73 based on the signal received from the flowmeter Sn2 so that the flow amount of the mixed solution is within a range appropriate for the separation by the membrane separator 72.

When the controller 90 activates the solution sending part 73 while opening the circulation valve 74 and the discharge valve 79, the mixed solution circulates the circulation route including the tank Tk1 and the circulation pipe 71. Accordingly, the mixed solution flows in the membrane separator 72. The membrane separator 72 separates the chemical solution from the mixed solution which has flowed, and flows the chemical solution to the discharge pipe 78. The mixed solution after separation continuously circulates the circulation pipe 71. In accordance with this separation, a concentration of the organic solvent (referred to as the solvent concentration hereinafter) in the mixed solution immediately after passing through the membrane separator 72 is higher than a solvent concentration of the mixed solution immediately before passing through the membrane separator 72 in the circulation pipe 71. Since the circulation part 7 circulates the mixed solution through the circulation pipe 71, the mixed solution continuously flows to the membrane separator 72. Thus, the membrane separator 72 continuously separates the chemical solution from the mixed solution. As a result, the chemical solution continuously flows from the discharge pipe 78. Since the solvent concentration in the chemical solution flowing in the discharge pipe 78 is low, the processing of discarding the chemical solution can be simplified.

In the meanwhile, the solvent concentration of the mixed solution during circulation gets higher as time proceeds. Thus, the solvent concentration of the mixed solution in the tank Tk1 gets high. The mixed solution with the increased solvent concentration may be reused as the organic solvent. For example, the circulation part 7 circulates the mixed solution until the solvent concentration of the mixed solution in the tank Tk1 is at least equal to or higher than a reuse reference value. The reuse reference value is previously set, for example. The reuse reference value may be equal to or higher than 80 vol %, equal to or higher than 85 vol %, or equal to or higher than 90 vol %, for example. The mixed solution having the solvent concentration equal to or higher than the reuse reference value is also referred to as a concentrated solution hereinafter.

In the example in FIG. 4, the collection unit 6 includes a concentration sensor Sn1. The concentration sensor Sn1 measures the solvent concentration of the mixed solution, and outputs an electrical signal indicating a measurement result thereof to the controller 90. In the example in FIG. 4, a concentration sensor Sn1 is provided to the circulation pipe 71. As a specific example, the concentration sensor Sn1 is located downstream of the membrane separator 72. The concentration sensor Sn1 may be provided to the tank Tk1. The controller 90 operates the circulation part 7 until the solvent concentration measured by the concentration sensor Sn1 is at least equal to or higher than the reuse reference value.

In the example in FIG. 4, the tank Tk1 of the collection unit 6 is connected to the processing unit 1 via a reuse pipe 65. In the example in FIG. 4, an upstream end portion of the reuse pipe 65 is connected to the bottom part, for example, of the tank Tk1. A downstream end portion of the reuse pipe 65 may be connected to the mixing part 45a. In this case, the reuse pipe 65 functions as the solvent supply pipe 44a. The supply valve 66 and the solution sending part 67 may be inserted into the reuse pipe 65. The supply valve 66 switches opening and closing of the reuse pipe 65. The solution sending part 67 sends the concentrated solution from the tank Tk1 toward the mixing part 45a. The controller 90 controls the supply valve 66 and the solution sending part 67.

The controller 90 activates the solution sending part 67 while opening the supply valve 66 in a state where the concentrated solution is stored in the tank Tk1. Accordingly, the concentrated solution in the tank Tk1 is supplied to the processing unit 1 through the reuse pipe 65. Since the organic solvent in the mixed solution used for the processing in the processing unit 1 is reused by the processing unit 1 while being included in the concentrated solution in this manner, a usage amount of the organic solvent can be reduced.

In the meanwhile, a component of the etching target may be included in the mixed solution used for processing the substrate W in the processing unit 1. When the etching target includes metal, the mixed solution includes metal (ion). That is to say, when the etching target (for example, the sacrifice film) of the substrate W is dissolved with the mixed solution, the metal included in the etching target is dissolved in the mixed solution. The metal includes at least any one of titanium, tantalum, and aluminum, for example. When the concentrated solution is used for processing the substrate W again while such metal is included in the concentrated solution in a high level, there is a possibility that performance of etching is reduced.

Thus, in the example in FIG. 4, the collection unit 6 also includes a first metal filter 76. In the example in FIG. 4, the first metal filter 76 is inserted into the circulation pipe 71. In the example in FIG. 3, the first metal filter 76 is located upstream of the membrane separator 72.

The first metal filter 76 traps the metal (ion) in the mixed solution. The first metal filter 76 includes an ion exchange resin and a filter housing for housing the ion exchange resin, for example. The ion exchange resin is synthetic resin having an ion exchange group. When the chemical solution flows in the first metal filter 76, the ion exchange group is exchanged with metal ions in the chemical solution. Accordingly, the metal ions are trapped by the ion exchange resin. The ion exchange resin may include a functional group forming a complex with the metal ions in the ion exchange group. Accordingly, the first metal filter 76 can trap the metal ions with higher selectivity.

Alternatively, the first metal filter 76 may include an adsorption agent and a filter housing for housing the adsorption agent. The adsorption agent adsorbs the metal ions in the chemical solution. The adsorption material may include at least any one of activated carbon, zeolite, and silica gel, for example.

In the example in FIG. 4, the first metal filter 76 is located upstream of the membrane separator 72. Accordingly, the mixed solution flows in the membrane separator 72 via the first metal filter 76. That is to say, a concentration of the metal (referred to as the metal concentration hereinafter) in the mixed solution is reduced by the first metal filter 76 before the mixed solution flows in the membrane separator 72. Thus, it is possible to reduce a possibility of the metal ion adhering to the separation membrane 72c of the membrane separator 72. Thus, deterioration of the separation membrane 72c can be reduced.

In the example in FIG. 4, the mixed solution continuously flows in the first metal filter 76 in circulation of the mixed solution. Thus, the first metal filter 76 continuously traps the metal in the mixed solution. Accordingly, the metal concentration of the mixed solution during circulation gets lower as time proceeds. The metal concentration can be further reduced by circulation through the first metal filter 76.

An example of an outline of an operation of the collection unit 6 is described next. The mixed solution after processing from the processing unit 1 flows in the tank Tk1. Firstly, the controller 90 controls the temperature adjustment part 75 so that the temperature of the mixed solution is adjusted to a temperature appropriate for separation by the membrane separator 72. Next, the controller 90 activates the solution sending part 73 while opening the circulation valve 74 and the discharge valve 79. Accordingly, the mixed solution circulates the circulation route including the tank Tk1 and the circulation pipe 71. When the decompression pump is provided to the discharge pipe 78, the controller 90 also activates the decompression pump. The chemical solution separated from the mixed solution by the membrane separator 72 is discharged outside through the discharge pipe 78, and the solvent concentration in the mixed solution during circulation increases as time proceeds.

When the first metal filter 76 is provided, the metal concentration of the mixed solution during circulation gets lower as time proceeds.

The controller 90 makes the circulation part 7 circulate the mixed solution until the solvent concentration of the mixed solution in the tank Tk1 is at least equal to or higher than the reuse reference value. Accordingly, the concentrated solution having the solvent concentration equal to or higher than the reuse reference value is stored in the tank Tk1. The controller 90 may make the circulation part 7 circulate the mixed solution until the metal concentration of the mixed solution in the tank Tk1 is equal to or lower than a metal reference value.

The collection unit 6 supplies the concentrated solution in the tank Tk1 to the processing unit 1 through the reuse pipe 65. Specifically, the controller 90 opens the supply valve 66 and activates the solution sending part 67. Accordingly, the concentrated solution in the tank Tk1 is supplied to the processing unit 1. The processing unit 1 may supply the concentrated solution to the processing unit 1 after stopping the operation of the circulation part 7, or may also supply the concentrated solution to the processing unit 1 in parallel to the operation of the circulation part 7.

As described above, the separation membrane 72c separates the chemical solution from the mixed solution of the chemical solution and organic solvent collected from the processing unit 1 in the substrate processing apparatus 100. Accordingly, the substrate processing apparatus 100 can separate the chemical solution from the mixed solution by lower energy compared with distillation, for example.

The separated chemical solution is discharged through the discharge pipe 78. Since the solvent concentration of this chemical solution is low, the processing of discarding the chemical solution can be further simplified.

In the meanwhile, the solvent concentration of the mixed solution gets high. In the example in FIG. 4, the collection unit 6 supplies the concentrated solution as the organic solvent to the processing unit 1 through the reuse pipe 65. That is to say, the organic solvent is reused. Thus, the usage amount of the organic solvent can be reduced. In other words, the substrate processing apparatus 100 contributes to saving of the organic solvent.

In the above example, the collection unit 6 includes the first metal filter 76. The first metal filter 76 traps the metal of the etching target included in the mixed solution. Thus, even when the metal concentration of the mixed solution after processing is increased by the etching processing on the substrate W, the metal concentration of the mixed solution can be reduced by the first metal filter 76. Thus, the collection unit 6 can supply a cleaner concentrated solution to the processing unit 1. Accordingly, the processing unit 1 can supply the mixed solution including the cleaner concentrated solution to the substrate W, thus can etch the substrate W while maintaining a high etching speed.

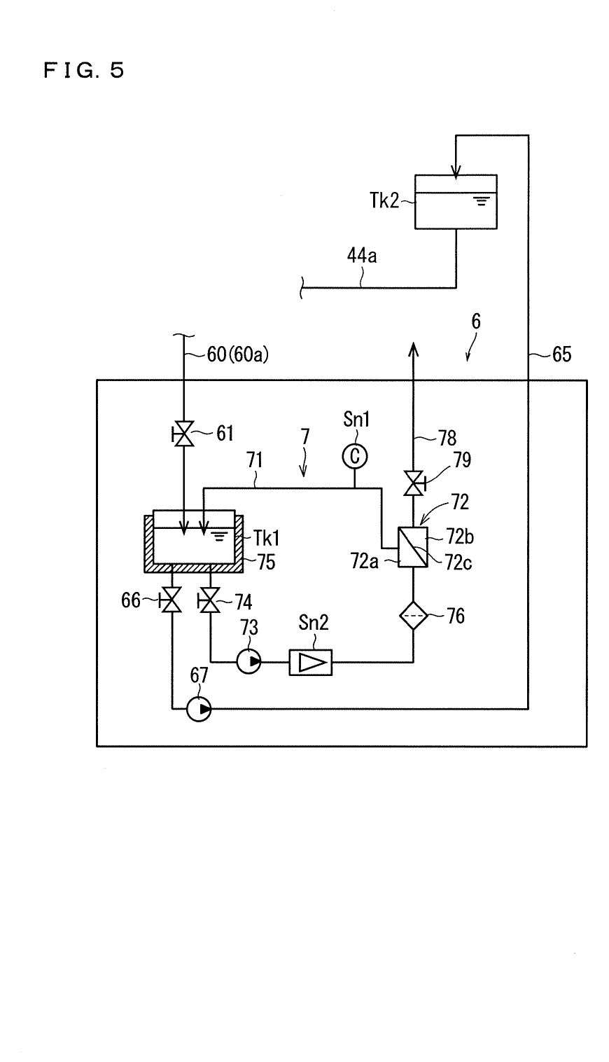

FIG. 5 is a diagram schematically illustrating a first another example of the configuration of the substrate processing apparatus 100. In the example in FIG. 5, a supply tank Tk2 is provided to the substrate processing apparatus 100. An organic solvent (concentrated solution) is stored in the supply tank Tk2. The downstream end portion of the reuse pipe 65 is connected to an upper part, for example, of the supply tank Tk2, and an upstream end portion of the solvent supply pipe 44a is connected to a bottom part, for example, of the supply tank Tk2. The supply tank Tk2 can function as a buffer tank. A solution sending part not shown in the diagrams may be inserted into the solvent supply pipe 44a.

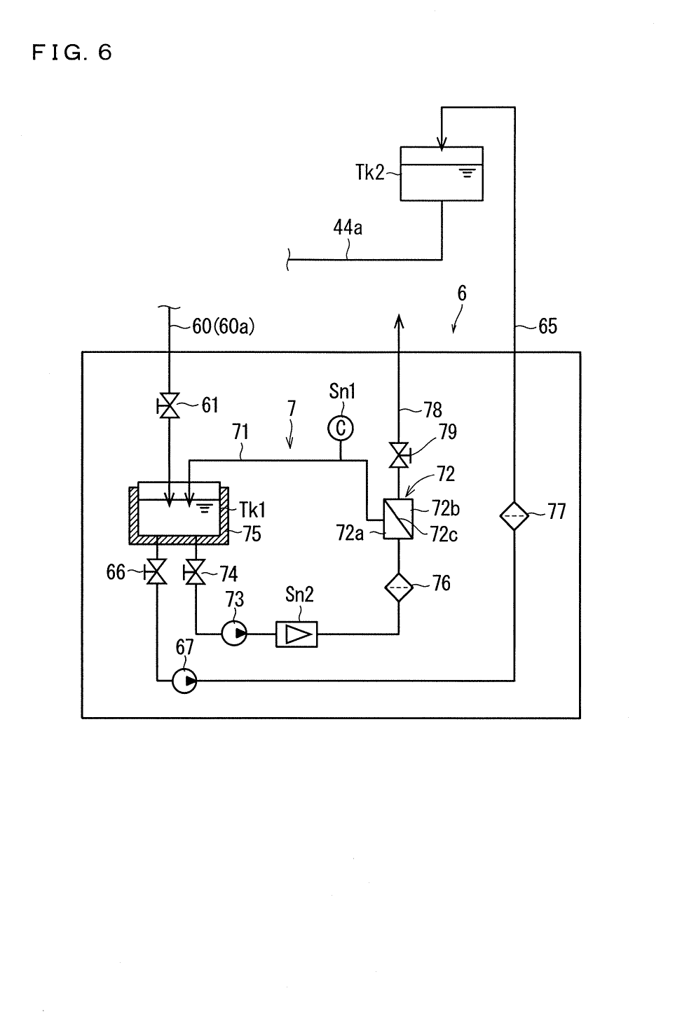

FIG. 6 is a diagram schematically illustrating a second another example of the configuration of the substrate processing apparatus 100. In the second another example, the substrate processing apparatus 100 further includes a second metal filter 77. The second metal filter 77 is inserted into the reuse pipe 65. The second metal filter 77 traps metal (ion) in the concentrated solution. An example of the second metal filter 77 may be similar to the first metal filter 76.

According to the second another example, the metal concentration of the concentrated solution can be further reduced by the second metal filter 77. Thus, the collection unit 6 can supply a cleaner concentrated solution to the processing unit 1.

Although the substrate processing apparatus 100 and the substrate processing method are described in detail above, the above description is in all aspects exemplary, and the present disclosure is not limited thereto. The various types of modification examples described above can be applied in combination unless any contradiction occurs. It is understood that countless modification examples that have not been exemplified can be assumed without departing from the scope of the present disclosure.

The present disclosure includes the following aspects.

A first aspect is a substrate processing apparatus including: a chamber in which a mixed solution of a chemical solution and an organic solvent acts on a main surface of a substrate; a collection pipe, with an upstream end portion connected to the chamber, into which the mixed solution from the chamber flows; and a collection unit including a separation membrane separating the chemical solution from the mixed solution supplied through the collection pipe to increase a concentration of the organic solvent in the mixed solution.

A second aspect is the substrate processing apparatus according to the first aspect, wherein the chemical solution is a liquid etching an etching target on the main surface of the substrate, the etching target includes metal, and the collection unit further includes a first metal filter trapping metal in the mixed solution.

A third aspect is the substrate processing apparatus according to the second aspect, wherein the collection unit includes: a tank to which the mixed solution flows through the collection pipe; and a circulation pipe, with an upstream end portion and a downstream end portion connected to the tank, into which the separation membrane and the first metal filter are inserted, and the first metal filter is located upstream of the separation membrane.

A fourth aspect is the substrate processing apparatus according to the second or third aspect, comprising: a reuse pipe in which the mixed solution with an increasing concentration of the organic solvent flows from the collection unit toward the chamber; and a second metal filter inserted into the reuse pipe to trap metal in the mixed solution.

According to the first aspect, the separation membrane separates the chemical solution from the mixed solution. Thus, the chemical solution can be separated from the mixed solution by lower energy compared with distillation, for example.

According to the second aspect, the mixed solution can be cleaned.

According to the third aspect, the metal flowing in the separation membrane can be reduced. Thus, deterioration of the separation membrane can be reduced.

According to the fourth aspect, the cleaner mixed solution can be supplied to the chamber.

While the disclosure has been shown and described in detail, the foregoing description is in all aspects illustrative and not restrictive. It is therefore understood that numerous modifications and variations can be devised.

What is claimed is:

1. A substrate processing apparatus, comprising:
a chamber in which a mixed solution of a chemical solution and an organic solvent acts on a main surface of a substrate;
a collection pipe, with an upstream end portion connected to the chamber, into which the mixed solution from the chamber flows; and
a collection unit including a separation membrane separating the chemical solution from the mixed solution supplied through the collection pipe to increase a concentration of the organic solvent in the mixed solution.

2. The substrate processing apparatus according to claim 1, wherein
the chemical solution is a liquid etching an etching target on the main surface of the substrate,
the etching target includes metal, and
the collection unit further includes a first metal filter trapping metal in the mixed solution.

3. The substrate processing apparatus according to claim 2, wherein
the collection unit includes:
a tank to which the mixed solution flows through the collection pipe; and
a circulation pipe, with an upstream end portion and a downstream end portion connected to the tank, into which the separation membrane and the first metal filter are inserted, and
the first metal filter is located upstream of the separation membrane.

4. The substrate processing apparatus according to claim 2, comprising:
a reuse pipe in which the mixed solution with an increasing concentration of the organic solvent flows from the collection unit toward the chamber; and
a second metal filter inserted into the reuse pipe to trap metal in the mixed solution.
